(19) United States
(12) Patent Application Publication
(10) Pub. No.: US 2012/0264302 A1
(43) Pub. Date: Oct. 18, 2012

(54) CHEMICAL MECHANICAL POLISHING PROCESS

(76) Inventors: Chun-Wei Hsu, Taipei City (TW); Teng-Chun Tsai, Tainan City (TW); Chia-Lin Hsu, Tainan City (TW); Po-Cheng Huang, Chiayi City (TW); Chia-Hsi Chen, Kao-Hsiung City (TW); Yen-Ming Chen, New Taipei City (TW); Chih-Hsun Lin, Ping-Tung County (TW)

(21) Appl. No.: 13/085,502

(22) Filed: Apr. 13, 2011

(51) Int. Cl. H01L 21/306

(52) U.S. Cl. 438/693; 438/692; 257/E21.23

(57) ABSTRACT

A chemical mechanical polishing (CMP) process includes steps of providing a substrate, performing a first polishing step to the substrate with an acidic slurry, and performing a second polishing step to the substrate with a basic slurry after the first polishing step.

### BACKGROUND OF THE INVENTION

1. Field of the Invention

The present invention relates to a chemical mechanical polishing (CMP) process, and more particularly, to a CMP process for dielectric materials.

2. Description of the Prior Art

Planarization is useful in semiconductor industries, among different approaches, the CMP process is a common technique widely used to remove excess deposited materials and to provide a planar surface for subsequent levels or processes.

In a conventional CMP process, the objective substrate is planarized by two important factors: One is the mechanical forces, applying onto the objective substrate through a rotating polishing pad. The other is the chemical composition, namely the slurry. The slurry initiates the polishing process by chemically reacting with the surface being polished.

In general, the CMP process is performed to planarize layer(s) deposited on a patterned layer or a structure. In one exemplar, in a manufacturing method for a semiconductor device having a metal gate involving gate-last process, after forming a transistor having a dummy gate patterned by a hard mask on a substrate, a dielectric layer is formed to cover the transistor and the substrate. Then, a CMP process is performed to remove the excessive dielectric material and the hard mask from the top of the dummy gate, thus to expose the dummy gate for following steps. In another exemplar, a CMP process is also used to remove excessive dielectric material from a substrate surface after filling a shallow trench with the dielectric material in a shallow trench isolation (STI) process.

However, serious problem such as the surface of the polished layer is contaminated by the residues of the slurry, polishing pad, or the polished layer is always found after the CMP process. In addition, byproducts made by the reaction between the slurry and the polished layer may adhere on the surface of polished layer after the CMP process. And those residues and byproducts are not easily removed from the polished layer even by performing post-CMP cleaning process.

Therefore, it is always in need to reduce the contamination on the polished layer during the CMP process and thus to improve the reliability of the semiconductor devices formed afterwards.

### SUMMARY OF THE INVENTION

According to a first aspect of the present invention, there is provided a chemical mechanical polishing (CMP) process. The CMP process includes steps of providing a substrate, performing a first polishing step to the substrate with an acidic slurry, and performing a second polishing step to the substrate with a basic slurry after the first polishing step.

According to a second aspect of the present invention, there is provided a method for manufacturing a semiconductor device. The method includes steps of providing a substrate having at least a transistor and a dielectric layer covering the transistor formed thereon, and the transistor comprising at least a dummy gate defined by a patterned hard mask; performing a first polishing step to remove a portion of the dielectric layer and a portion of the patterned hard mask with a Ceria slurry; performing a second polishing step to remove a portion of the dielectric layer and at least a portion of the patterned hard mask with an acidic slurry; and performing a third polishing step to remove at least a portion of the dielectric layer with a basic slurry.

According to a third aspect of the present invention, there is provided a method for manufacturing a semiconductor device. The method includes steps of providing a substrate having at least a transistor and a dielectric layer covering the transistor formed thereon, and the transistor comprising at least a metal gate; performing a first polishing step to remove a portion of the dielectric layer with a Ceria slurry; performing a second polishing step to remove the portion of the dielectric layer with an acidic slurry; and performing a third polishing step to remove the portion of the dielectric layer to form an even surface.

According to the CMP process and the methods for manufacturing a semiconductor device applied with a CMP process provided by the present invention, the residues left from the polishing steps using the acidic slurries are removed by performing the polishing step using the basic slurry. Accordingly, the contamination on the polished layer is reduced and thus the reliability of the semiconductor devices fabricated by the provided methods is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a CMP process provided by a preferred embodiment of the present invention;

FIGS. 2-3 are schematic drawings illustrating the progressive steps of the CMP process for fabricating a STI structure according to a first preferred embodiment of the present invention;

FIGS. 4-6 are schematic drawings illustrating the progressive steps of the CMP process for fabricating a semiconductor device having a metal gate according to a second preferred embodiment of the present invention;

FIG. 7-8 are schematic drawings illustrating a modification to the second preferred embodiment of the present invention; and

FIGS. 9-10 are schematic drawings illustrating the progressive steps of the CMP process for fabricating a semiconductor device having a metal gate according to a third preferred embodiment of the present invention.

### DETAILED DESCRIPTION

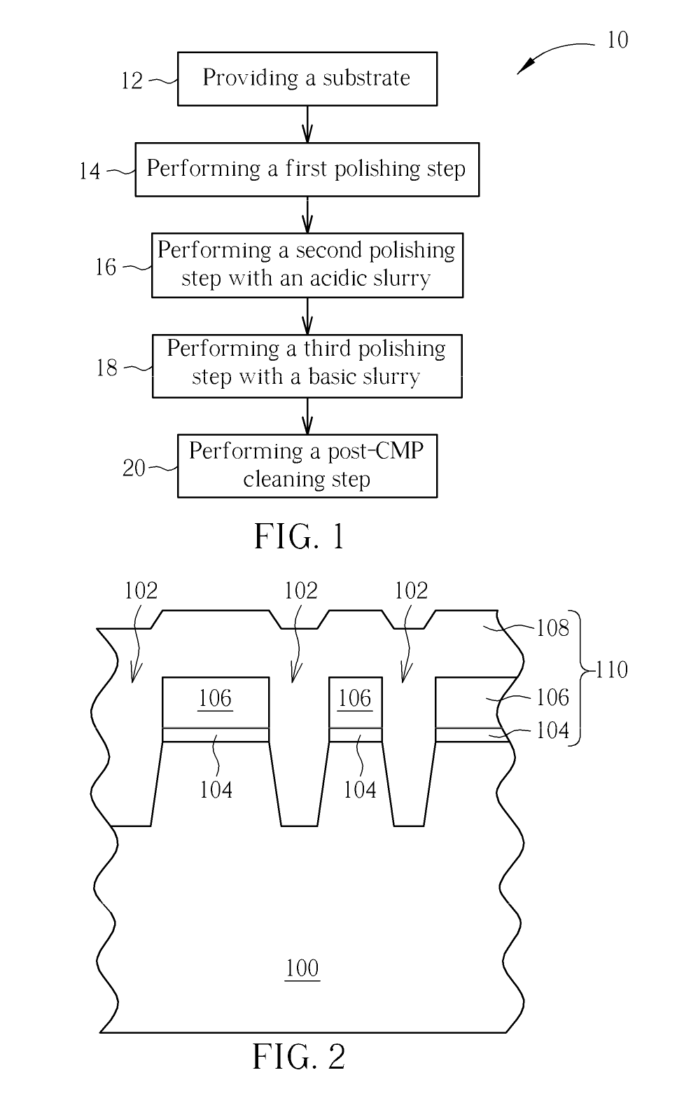

Please refer to FIG. 1, which is a flow chart of a CMP process provided by a preferred embodiment of the present invention. As shown in FIG. 1, a CMP process 10 provided by the preferred embodiment includes:

Step 12: providing a substrate

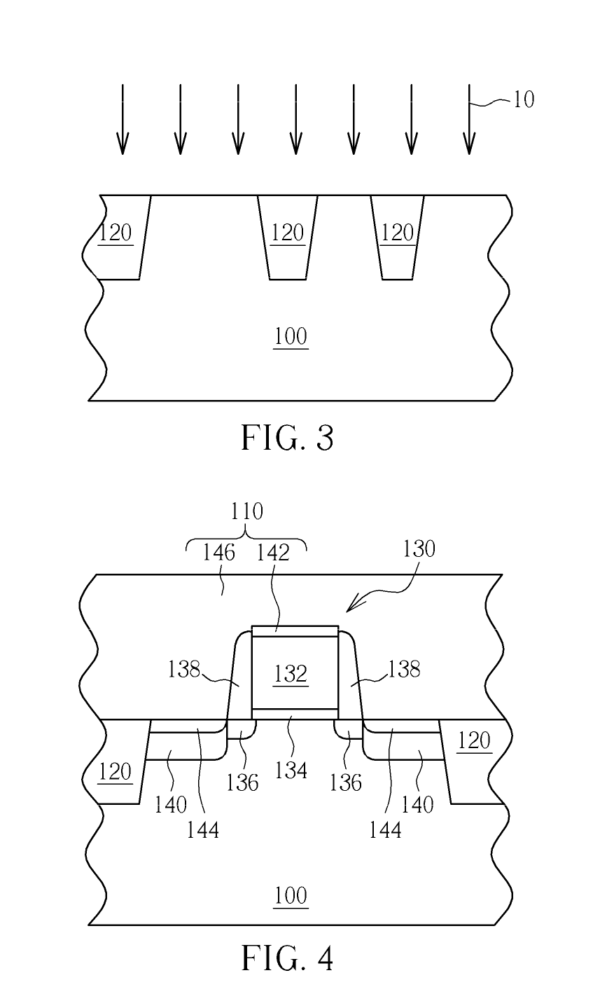

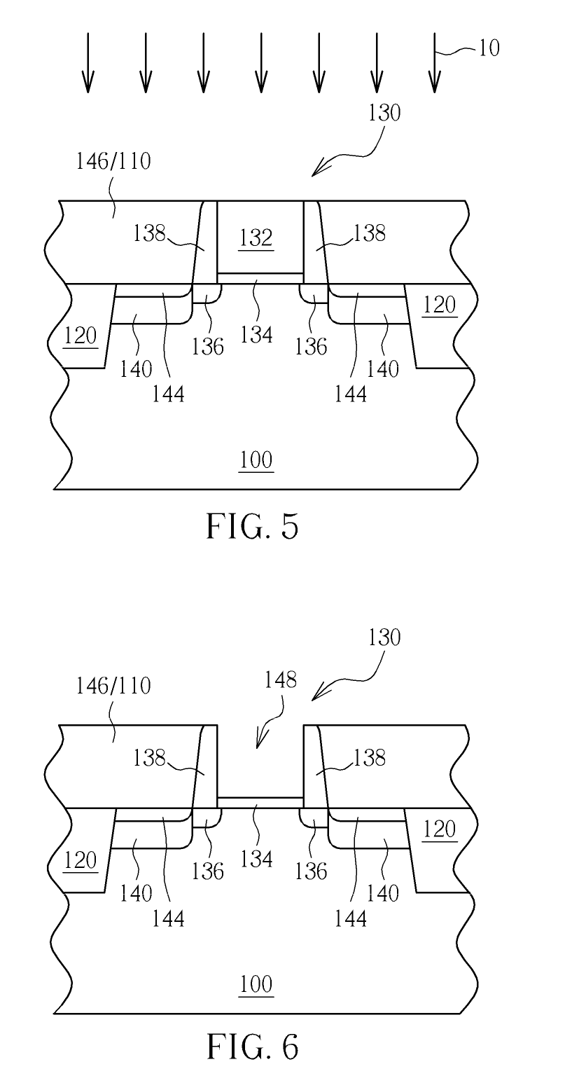

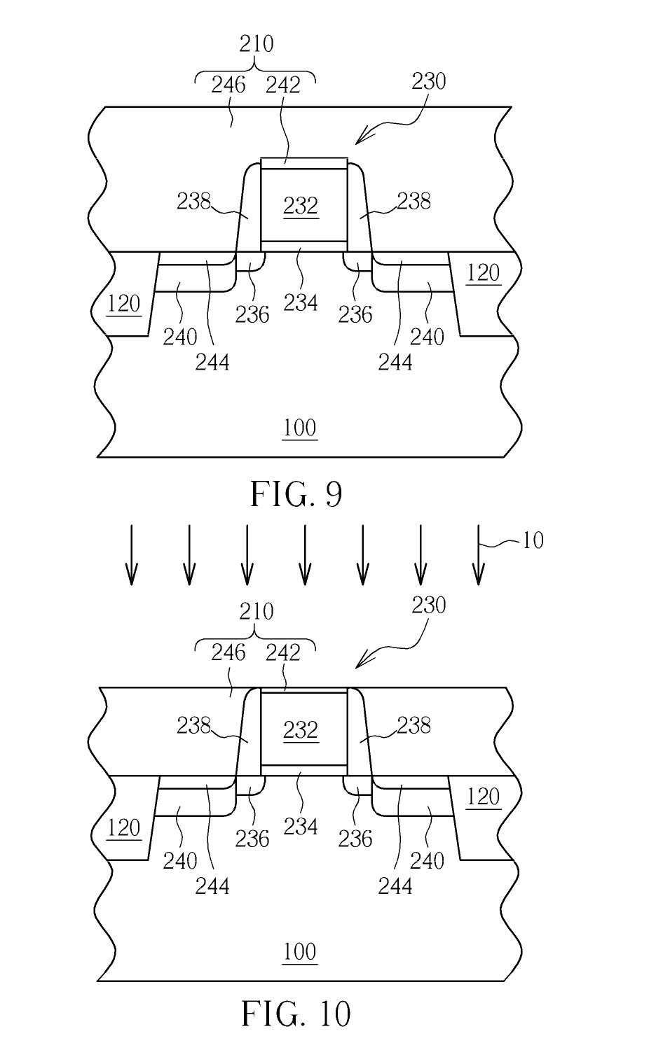

In Step 12, a substrate 100 is provided. The substrate 100 includes a multi-layered dielectric structure 110 formed thereon. The substrate 100 further includes at least a shallow trench pattern (shown in FIG. 2) formed therein or at least a semiconductor device (shown in FIG. 4 and FIG. 9) covered by the multi-layered dielectric structure 110. After Step 12, a Step 14 is followed:

Step 14: performing a first polishing step

In Step 14, a first polishing step is performed to the substrate 100 with at least a Ceria slurry, but not limited to this. And the Ceria slurry is an acidic slurry having a pH of 4 to 5. After Step 14, a Step 16 is followed:

Step 16: performing a second polishing step with an acidic slurry

In Step 16, a second polishing step is performed to the substrate 100 with an acidic slurry, and the acidic slurry has a pH between 4 and 5. In the preferred embodiment, the acidic slurry further includes at least a colloid silica slurry, but not limited to this. After Step 16, a Step 18 is followed:

Step 18: performing a third polishing step

In step 18, a third polishing step is performed to the substrate 100 with a basic slurry. It is noteworthy that the third polishing step involves the basic slurry having a pH of 7 to 12 while the first polishing step of Step 14 and the second polishing step of Step 16 all using acidic slurries. According to the preferred embodiment, the basic slurry further includes at least a dispersant and a stabilizer. The dispersant of the basic slurry is selected from the group of hydrochloric acid (HCl), sulfuric acid (H₂SO₄), nitric acid (HNO₃), phosphoric acid (H₃PO₄), acetic acid (CH₃COOH), and maleic acid. The stabilizer of the basic slurry is selected from the group of sodium hydroxide (NaOH), Potassium hydroxide (KOH), lithium hydroxide (LiOH), ammonium hydroxide (NH₄OH), triethylamine, and dimethylethanol amine (DMEA). It is well-known to those skilled in the art that the CMP process 10 also always involves mechanical forces from a polishing pad, and the polishing pad required in the third polishing step of Step 18 of the preferred embodiment further has a down force lower than 1.5 psi.

In addition, the basic slurry used in the third polishing step of Step 18 selectively includes at least a silica abrasive, and the silicon abrasive is selected from the group of fumed silica and colloid silica. After Step 18, a Step 20 is followed:

Step 20: performing a post-CMP cleaning step.

In step 20, a post-CMP cleaning step is performed to the substrate 100. The post-CMP cleaning step of Step 20 can be a multi-stepped process. Accordingly, the post-CMP process of Step 20 is to clean the polished substrate 100 sequentially with a megasonic cleaning, a first brush cleaning and a second brush cleaning. The megasonic cleaning may be carried out in a conventional megasonic cleaning apparatus, typically using an SC-1 cleaning solution that contains NH₄OH, hydrogen peroxide (H₂O₂) and DI (deionized) water, according to the knowledge of those skilled in the art. The first brushing cleaning and the second brushing cleaning are carried out respectively with dilute hydrofluoric acid (DHF) and ammonia hydroxide (NH₄OH), according to the knowledge of those skilled in the art. Those skilled in art would easily realize that process order and the chemicals used in the megasonic cleaning, the first brush cleaning and the second brush cleaning mentioned above are only exemplarily disclosed and are not limited to this.

Please refer to FIGS. 1-3, which are schematic drawings illustrating the progressive steps of the CMP process 10 for fabricating an STI structure according to a first preferred embodiment of the present invention. During the fabrication of the STI, a plurality of shallow trenches 102 is formed on the substrate 100 by etching the substrate 100 through a patterned oxide layer 104 and a patterned nitride layer 106. Then, a dielectric material 108 such as a chemical vapor deposition (CVD) oxide is deposited over the substrate 100 to fill the shallow trenches 102. As shown in FIG. 2, the patterned oxide layer 104, the patterned nitride layer 106, and the dielectric material 108 filling the shallow trenches 102 form the multi-layered dielectric structure 110. In other words, the preferred embodiment first provides the substrate 100 having at least a shallow trench pattern covered by the multi-layered dielectric structure 110 which includes the patterned oxide layer 104, the patterned nitride layer 106, and the dielectric material 108.

Please refer to FIGS. 1 and 3. After providing the substrate 100, the CMP process 10 is performed to remove a portion of the multi-layered dielectric structure 110 to form at least an STI 120. It is found that during the first polishing step of Step 14 and the second polishing step of Step 16 of the CMP process 10, massive residues, most of the residues are SiO₂, are formed. And SiO₂ is apt to adhere on surface of the substrate 100 in the acidic environment. Furthermore, it is extremely difficult to remove SiO₂ adhered on the substrate 100 by the post-CMP cleaning step of Step 20. As a countermeasure against to the problems, Step 18 is performed to remove the portion of the multi-layered dielectric structure 110 with the third polishing step using the basic slurry. In the third polishing step of Step 18, SiO₂ loses its adhesion to the substrate 100 and is easily removed in the third polishing step of Step 18 and the post-CMP cleaning step of Step 20 that is subsequently performed. Accordingly, STI 120 is formed and a substantially even surface of the substrate 100 is obtained.

According to the first preferred embodiment, the third polishing step of Step 18 is performed to polish the multi-layered dielectric structure 110 in a basic environment, therefore the residues such as SiO₂ are easily removed in the third polishing step and the post-CMP cleaning step of the CMP process 10. Since the residues are removed, the substrate 100 provides an even and clean surface ready for the following manufacturing processes.

Please refer to FIGS. 1 and 4-6, which are schematic drawings illustrating the progressive steps of the CMP process 10 for fabricating a semiconductor device having a metal gate according to a second preferred embodiment of the present invention. According to the preferred embodiment, the semiconductor device have a metal gate is fabricated with a gate-last approach applied. As shown in FIG. 4, the substrate 100 having at least a semiconductor device such as a transistor 130 formed thereon is provided. Since the semiconductor device is fabricated with the gate-last approach, the transistor 130 includes a dummy gate 132 defined by a patterned hard mask 142, which includes conventionally a silicon nitride. The dummy gate 132 includes polysilicon conventionally, but not limited to this. The transistor 130 also includes a gate dielectric layer 134, source/drain extension regions 136 formed in the substrate 100 at two sides of the dummy gate 132, a spacer 138 formed on sidewalls of the dummy gate 132, a source/drain 140 formed in the substrate 100 at two sides of the spacer 138, and silicides 144 formed on surfaces of the source/drain 140. As shown in FIG. 4, the substrate 100 further includes a dielectric layer 146 covering the transistor 130. It is noteworthy that the dielectric layer 146 and the patterned hard mask 142 form a multi-layered dielectric structure 110, and the transistor 130 is covered by the multi-layered dielectric structure 110.

Please refer to FIGS. 1 and 5. Then, the CMP process 10 is performed as mentioned above: Step 14 is performed to remove a portion of multi-layered dielectric structure 110 that is a portion of the dielectric layer 146 and a portion of the patterned hard mask 142 with the first polishing step using the Ceria slurry. In particularly, the first polishing step of Step 14 is performed to remove the dielectric layer 146 to expose the patterned hard mask 142.

Please still refer to FIGS. 1 and 5. Then, Step 16 and Step 18 of the CMP process 10 are sequentially performed to remove the portion of the multi-layered dielectric structure 110, that is the portion of the dielectric layer 146 and the patterned hard mask 142, to expose a top of the dummy gate 132 as shown in FIG. 5. In detail, the second polishing step of Step 16 is performed to remove a portion of the dielectric layer 100 and the entire patterned hard mask 142, thus a top of the dummy gate 132 is exposed. Subsequently, the third polishing step of Step 18 is performed to remove a portion of the dielectric layer 110 and a portion of the dummy gate 132. As mentioned above, the second polishing step of Step 16 is performed with the acidic slurry; and the third polishing step of Step 18 is performed with the basic slurry. It is found that during the first polishing step of Step 14 and the second polishing step of Step 16 of the CMP process 10, massive residues, most of the residues are SiO₂, are formed. And SiO₂ is apt to adhere on surface of the substrate 100 in the acidic environment. Therefore Step 18 is performed to remove the portion of the multi-layered dielectric structure 110 with the third polishing step using the basic slurry. In the basic environment provided by the third polishing step of Step 18, SiO₂ loses its adhesion to the substrate 100 and is easily removed in the third polishing step of Step 18 and the post-CMP cleaning step of Step 20 that is subsequently performed. Accordingly, the top of the dummy gate 132 is exposed as shown in FIG. 5.

Please refer to FIG. 6. Then, the exposed dummy gate 132 is removed to form a gate trench 148 with the gate dielectric layer 134 exposed in the bottom of the gate trench 148. Subsequently, gate-last approach that includes forming work function metal layer and filling metal layer is performed. Those skilled in art would easily realize that the high-K last approach, that is to remove the original gate dielectric layer 134 and subsequently to form a high-K dielectric in the bottom of the gate trench 148, can be performed in the preferred embodiment.

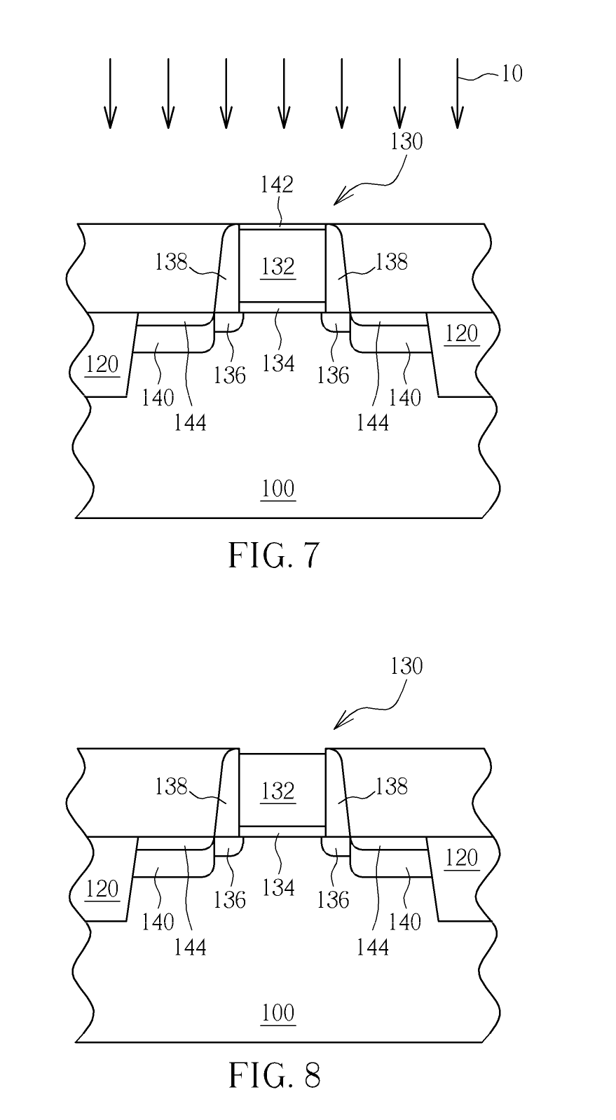

Please refer to FIG. 1 and FIG. 7-8, which are schematic drawings illustrating a modification to the second preferred embodiment of the present invention. According to the modification, the semiconductor device have a metal gate is fabricated with a gate-last approach applied. As shown in FIGS. 1 and 7, the CMP process 10 is performed by first performing Step 14 to remove a portion of the multi-layered dielectric structure 110 that is a portion of the dielectric layer 146 and a portion of the patterned hard mask 142 with first polishing step using the Ceria slurry. In particularly, the first polishing step of Step 14 is performed to remove the dielectric layer 146 to expose the patterned hard mask 142.

Please still refer to FIGS. 1 and 7. Then, Step 16 and Step 18 of the CMP process 10 are sequentially performed to remove a portion of the multi-layered dielectric structure 110, that is a portion of the dielectric layer 146 and a portion of the patterned hard mask 142. It is noteworthy that Step 16 and Step 18 are performed to remove the portion of the multi-layered dielectric structure 110 without exposing the dummy gate 132 as shown in FIG. 7.

Please refer to FIG. 8. Then, the remained patterned hard mask 142 is removed by performing another etching process. Consequently, the dummy gate 132 is exposed after the etching process. Next, the exposed dummy gate 132 is removed to form a gate trench 148 with the gate dielectric layer 134 exposed in the bottom of the gate trench 148 as shown in FIG. 6. Subsequently, gate-last approach that includes forming work function metal layer and filling metal layer is performed. Those skilled in art would easily realize that the high-K last approach, that is to remove the original gate dielectric layer 134 and subsequently to form a high-K dielectric in the bottom of the gate trench 148, can be performed in the preferred embodiment.

Because etching rate of the dielectric layer 146 and of the patterned hard mask 142 are different from each other even in the CMP process 10, the dielectric layer 146 may have been damaged when the patterned hard mask 142 is completely removed. Thus defects such as dish are undesirably resulted. Therefore, the modification is performed to remove only the portion of the dielectric layer 146 and the portion of the patterned hard mask 142 without completely removing the patterned hard mask 142. Accordingly, the surface of dielectric layer 146 and the patterned hard mask 142 remain co-planar. Then, the patterned hard mask 142 is removed by another etching process without impacting the dielectric layer 146. Therefore the defects as mentioned above are avoided.

According to the second preferred embodiment, the third polishing step of Step 18 is performed to polished the multi-layered dielectric structure 110 in the basic environment, therefore the residues such as SiO₂ are easily removed in the third polishing step and the post-CMP cleaning step of the CMP process 10. Since the residues are eliminated, the removal of the dummy gate 132 is carried out completely, and a substantially clean gate trench 148 is obtained and ready for forming the metal layers.

Please refer to FIGS. 1 and 9-10, which are schematic drawings illustrating the progressive steps of the CMP process 10 for fabricating a semiconductor device having a metal gate according to a third preferred embodiment of the present invention. According to the preferred embodiment, the semiconductor device have a metal gate is fabricated with a gate-first approach applied. As shown in FIG. 9, the substrate 100 having at least a semiconductor device such as a transistor 230 formed thereon is provided. Since the semiconductor device is fabricated with the gate-last approach, the transistor 230 includes a metal gate 232 defined by a patterned hard mask 242, which includes conventionally a silicon nitride. The metal gate 232 conventionally includes at least a work function metal (not shown). The transistor 230 also includes a gate dielectric layer 234, source/drain extension regions 236 formed in the substrate 100 at two sides of the metal gate 232, a spacer 238 formed on sidewalls of the metal gate 232, a source/drain 240 formed in the substrate 100 at two sides of the spacer 238, and silicides 244 formed on surfaces of the source/drain 240. As shown in FIG. 9, the substrate 100 further includes a dielectric layer 246 covering the transistor 230. It is noteworthy that the dielectric layer 246 and the patterned hard mask 242 form a multi-layered dielectric structure 210, and the transistor 230 is covered by the multi-layered dielectric structure 210.

Please refer to FIGS. 1 and 9. Then, the CMP process 10 is performed as mentioned above: Step 14 is performed to remove a portion of multi-layered dielectric structure 210 that is a portion of the dielectric layer 246 and a portion of the patterned hard mask 242 with the first polishing step using the Ceria slurry. Then Step 16 and Step 18 of the CMP process 10 are sequentially performed to remove a portion of the multi-layered dielectric structure 210, that is a portion of the dielectric layer 246 and a portion of the patterned hard mask 242. As mentioned above, the second polishing step of Step 16 is performed with the acidic slurry; and the third polishing step of Step 18 is performed with the basic slurry. It is found that in the first polishing step of Step 14 and the second polishing step of Step 16 of the CMP process 10, massive residues, most of the residues are SiO₂, are formed. And SiO₂ is apt to adhere on surface of the substrate 100 in the acidic environment. Therefore Step 18 is performed to remove a portion of the multi-layered dielectric structure 210 with the third polishing step using the basic slurry. In the basic environment provided by the third polishing step of Step 18, SiO₂ loses its adhesion to the substrate 100 and is easily removed in the third polishing step of Step 18 and the post-CMP cleaning step of Step 20 that is subsequently performed. Accordingly, a substantially even surface of the multi-layered dielectric structure 210 is obtained. It is noteworthy that the semiconductor device 230 and the multi-layered dielectric structure 210 after the CMP process 10 are co-planar.

According to the third preferred embodiment, the third polishing step of Step 18 is performed to polish the multi-layered dielectric structure 210 in the basic environment, therefore the residues such as SiO₂ are easily removed in the third polishing step of Step 18 and the post-CMP cleaning step of Step 20 of the CMP process 10. Since the residues are removed, the multi-layered structure 210 provides an even and clean surface ready for following manufacturing processes. More important, the reliability of the semiconductor devices 230 fabricated by the preferred embodiment is improved because the residue defects are reduced.

According to the CMP process and the methods for manufacturing a semiconductor device applied with a CMP process provided by the present invention, the residues left from the polishing steps using the acidic slurries are removed by performing the polishing step using the basic slurry. Accordingly, the contamination on the polished layer is reduced and thus the reliability of the semiconductor devices fabricated by the provided methods is improved. Furthermore, since the residues generated in the acidic slurry are easily removed by the polishing step having the basic slurry, lifetime of the polishing pad used in the polishing step having the basic slurry is prolonged from 4 hours to 8-9 hours.

Those skilled in the art will readily observe that numerous modifications and alterations of the device and method may be made while retaining the teachings of the invention.

What is claimed is:

1. A chemical mechanical polishing (CMP) process comprising steps of:
providing a substrate;
performing a first polishing step to the substrate with an acidic slurry; and
performing a second polishing step to the substrate with a basic slurry after the first polishing step.

2. The CMP process according to claim 1, wherein the basic slurry has a pH of 7 to 12.

3. The CMP process according to claim 1, wherein the basic slurry further comprises at least a dispersant and a stabilizer.

4. The CMP process according to claim 3, wherein the dispersant is selected from the group of hydrochloric acid (HCl), sulfuric acid (H₂SO₄), nitric acid (HNO₃), phosphoric acid (H₃PO₄), acetic acid (CH₃COOH), and maleic acid.

5. The CMP process according to claim 3, wherein the stabilizer is selected from the group of sodium hydroxide (NaOH), Potassium hydroxide (KOH), lithium hydroxide (LiOH), ammonium hydroxide (NH₄OH), triethylamine, and dimethylethanol amine (DMEA).

6. The CMP process according to claim 1, wherein the basic slurry further comprises at least a silica abrasive.

7. The CMP process according to claim 6, wherein the silicon abrasive is selected from the group of fumed silica and colloid silica.

8. The CMP process according to claim 1, wherein the acidic slurry further comprises at least a colloid silica slurry.

9. The CMP process according to claim 1, further comprising a step of performing a third polishing step with at least a Ceria slurry before the first polishing step, and the Ceria slurry is an acidic slurry.

10. The CMP process according to claim 1, wherein the substrate comprises a multi-layered dielectric structure formed thereon.

11. The CMP process according to claim 10, wherein the substrate further comprises at least a semiconductor device or at least a shallow trench formed covered by the multi-layered dielectric structure.

12. The CMP process according to claim 11, wherein the CMP process is performed to a portion of the multi-layered dielectric structure to expose a top of the semiconductor device.

13. The CMP process according to claim 11, wherein the CMP process is performed to remove a portion of the multi-layered dielectric structure to form a substantially even surface, and the semiconductor device and the multi-layered dielectric structure after the CMPS process are co-planar.

14. The CMP process according to claim 11, wherein the CMP process is performed to remove a portion of the multi-layered dielectric structure to form at least a shallow trench isolation (STI) in the shallow trench and a substantially even surface.

15. A method for manufacturing a semiconductor device comprising steps of:
providing a substrate having at least a transistor and a dielectric layer covering the transistor formed thereon, and the transistor comprising at least a dummy gate defined by a patterned hard mask;
performing a first polishing step to remove a portion of the dielectric layer and a portion of the patterned hard mask with a Ceria slurry;
performing a second polishing step to remove a portion of the dielectric layer and at least a portion of the patterned hard mask with an acidic slurry; and
performing a third polishing step to remove a portion of the dielectric layer with a basic slurry.

16. The method for manufacturing a semiconductor device according to claim 15, wherein the basic slurry has a pH of 7 to 12.

17. The method for manufacturing a semiconductor device according to claim 15, wherein the basic slurry further comprises at least a dispersant and a stabilizer.

18. The method for manufacturing a semiconductor device according to claim 17, wherein the dispersant is selected from the group of hydrochloric acid (HCl), sulfuric acid (H₂SO₄), nitric acid (HNO₃), phosphoric acid (H₃PO₄), acetic acid (CH₃COOH), and maleic acid.

19. The method for manufacturing a semiconductor device according to claim 17, wherein the stabilizer is selected from the group of sodium hydroxide (NaOH), Potassium hydroxide (KOH), lithium hydroxide (LiOH), ammonium hydroxide (NH₄OH), triethylamine, and dimethylethanol amine (DMEA).

20. The method for manufacturing a semiconductor device according to claim 15, wherein the basic slurry further comprises at least a silica abrasive.

21. The method for manufacturing a semiconductor device according to claim 20, wherein the silicon abrasive is selected from the group of fumed silica and colloid silica.

22. The method for manufacturing a semiconductor device according to claim 15, wherein the acidic slurry further comprises at least a colloid silica slurry.

23. The method for manufacturing a semiconductor device according to claim 15, wherein the Ceria slurry is an acidic slurry.

24. The method for manufacturing a semiconductor device according to claim 15, wherein the second polishing step removes the patterned hard mask to expose a top of the dummy gate and the third polishing step further removes a portion of the dummy gate.

25. The method for manufacturing a semiconductor device according to claim 15, wherein the second polishing step removes the portion of the patterned hard mask and the third polishing step removes a portion of the patterned hard mask without exposing the dummy gate.

26. The method for manufacturing a semiconductor device according to claim 15, further comprising a step of removing the dummy gate after the third polishing step.

27. The method for manufacturing a semiconductor device according to claim 15, further comprising a step of performing a post-CMP cleaning step after the third polishing step.

28. A method for manufacturing a semiconductor device comprising steps of:
providing a substrate having at least a transistor and a dielectric layer covering the transistor formed thereon, the transistor further including a metal gate;
performing a first polishing step to remove a portion of the dielectric layer with a Ceria slurry;
performing a second polishing step to remove the portion of the dielectric layer with an acidic slurry; and
performing a third polishing step to remove the portion of the dielectric layer to form an even surface.
